(19) United States
(12) Patent Application Publication
(10) Pub. No.: US 2012/0235764 A1
(43) Pub. Date: Sep. 20, 2012

(54) STRUCTURE OF TRANSMISSION LINE FOR DATA COMMUNICATION AND METHOD FOR DESIGNING THE SAME

(75) Inventors: Sae Kyoung KANG, Daejeon (KR); Joon Ki LEE, Daejeon (KR); Joon Young HUH, Daejeon (KR); Jyung Chan LEE, Daejeon (KR)

(73) Assignee: Electronics and Telecommunications Research Institute, Daejeon (KR)

(21) Appl. No.: 13/365,491

(22) Filed: Feb. 3, 2012

(30) Foreign Application Priority Data
Mar. 15, 2011 (KR) 10-2011-0022970

(51) Int. Cl. H01P 3/08; H05K 3/10; H03H 7/38

(52) U.S. Cl. 333/26; 333/238; 29/846

(57) ABSTRACT

Disclosed is a structure for impedance matching by applying a CPW structure to an impedance discontinuous portion on a data signal line or using a micro-strip open stub so as to be used for high-speed transmission by a flexible PCB. According to the present invention, it is possible to fabricate a flexible PCB capable of performing low-priced and high-speed transmission.

### CROSS-REFERENCE TO RELATED APPLICATIONS

This application claims priority to and the benefit of Korean Patent Application No. 10-2011-0022970 filed in the Korean Intellectual Property Office on Mar. 15, 2011, the entire contents of which are incorporated herein by reference.

### TECHNICAL FIELD

The present invention relates to a structure of a transmission line for data communication and a method for designing the same. More particularly, the present invention relates to a structure of a transmission line for data communication according to a printed circuit board (PCB) and a method for designing the same by using the printed circuit board (PCB).

### BACKGROUND ART

A flexible PCB is one type of PCBs which are used for various uses in a communication system. The largest merit of the flexible PCB is in that the flexible PCB may provide a lot of degrees of freedom in the design of a system due to variability of shapes thereof. Currently, the flexible PCB is mainly used at a low transmission speed, but a flexible PCB operating at a high transmission speed will be required in electric connection fields of future optical communication devices.

As the flexible PCB capable of operating in a high frequency domain, a method of separating a signal ground and a frame ground from the flexible PCB in an optical transceiver structure by using a parallel plate capacitor was provided. However, the signal line structure on the flexible PCB used in the method is a structure which is generally used at a transmission speed of 10 Gbps level or less. Accordingly, it is difficult to use the signal line structure at the transmission speed of 10 Gbps level or more according to the increase in a reflection.

As the flexible PCB capable of operating in the high frequency domain, in order to solve the impedance mismatch generated when the flexible PCB is connected with the main board, a method of compensating the impedance mismatch with a parallel capacitor component between the signal line and the ground by making a ground via hole at both sides of the signal line was provided. However, the method has disadvantages in that there is a limitation to a channel distance by a via hole when using a differential signal or various channel signals and the entire size of the flexible PCB increases because a distance between the via hole and the signal line needs to more increase at a higher frequency than the frequency band.

### SUMMARY OF THE INVENTION

The present invention has been made in an effort to provide a structure of a transmission line for data communication impedance-matching data signal lines between a flexible PCB and a main board by using a coplanar waveguide (CPW) structure or an open stub of a micro-strip transmission line and a method for designing a transmission line for data communication.

An exemplary embodiment of the present invention provides a structure of a transmission line for data communication, including: a first substrate layer with a data transmission line at one side thereof; and a second substrate layer having at least a part stacked on the first substrate layer and including a first layer serving as a GND and a second layer provided on the first layer and having a data communication pattern connected to the data transmission line and GND patterns which are not parallel to the data communication pattern which are formed at one side thereof.

The first layer may have a discontinuous surface formed at one side thereof and the second layer may have only the data communication pattern disposed on the discontinuous surface so as not to be parallel to the GND patterns.

The second layer may have the data communication pattern so as not to be parallel to the GND patterns through first impedance matching patterns extending from at least one side of the GND patterns to protrude toward the data communication pattern. One end of the first impedance matching patterns may be formed to protrude more toward the data communication pattern than the other end thereof. The first impedance matching patterns may be disposed at the ends of the GND patterns.

The second layer may have the data communication pattern so as not to be parallel to the GND patterns through a second impedance matching pattern extending from at least one side of the data communication pattern to protrude toward the GND patterns. One end and the other end of the second impedance matching pattern may be formed to equally protrude toward the GND patterns. When the second impedance matching pattern is formed at one side of the data communication pattern, a length of the second impedance matching pattern may be set to have a larger value than a width of the second impedance matching pattern and when the second impedance matching pattern is formed at both sides of the data communication pattern, the width of the second impedance matching pattern may be set to have a larger value than the length of the second impedance matching pattern.

The second impedance matching pattern may be formed at the side which does not face the GND patterns.

The second substrate layer may be flexible.

Another exemplary embodiment of the present invention provides a method for designing a transmission line for data communication, including: forming a data transmission line at one side of a first substrate layer; stacking at least a part of a second substrate layer having a first layer serving as a GND at the bottom thereof on the first substrate layer; and forming a data communication pattern connected to the data transmission line and GND patterns which are not parallel to the data transmission pattern at one side of a second layer disposed on the first layer included in the second substrate layer.

In the stacking, a discontinuous surface may be formed at one side of the first layer and in the forming of the patterns, only the data communication pattern disposed on the discontinuous surface may be formed so as not to be parallel to the GND patterns.

In the forming of the patterns, the data communication pattern may be formed so as not to be parallel to the GND patterns by forming first impedance matching patterns extending from at least one side of the GND patterns so as to protrude toward the data communication pattern. In the forming of the patterns, one end of the first impedance matching patterns may be formed to protrude more toward the data communication pattern than the other end of the first impedance matching patterns. In the forming of the patterns, the first impedance matching patterns may be formed at the end of the GND patterns.

In the forming of the patterns, the data communication pattern may be formed so as not to be parallel to the GND patterns by forming a second impedance matching pattern extending from at least one side of the data communication pattern so as to protrude toward the GND patterns. In the forming of the patterns, one end and the other end of the second impedance matching pattern may be formed to equally protrude toward the GND patterns. In the forming of the patterns, when the second impedance matching pattern is formed at one side of the data communication pattern, a length of the second impedance matching pattern may be set to have a larger value than a width of the second impedance matching pattern and when the second impedance matching pattern is formed at both sides of the data communication pattern, the width of the second impedance matching pattern may be set to have a larger value than the length of the second impedance matching pattern.

In the forming of the patterns, the second impedance matching pattern may be formed at the side which does not face the GND patterns.

In the forming of the patterns, the second substrate layer may use a flexible printed circuit board (PCB).

According to exemplary embodiments of the present invention, it is possible to largely improve a reflection by generating a resonance in a desired frequency band by impedance-matching data signal lines between the flexible PCB and the main board by using a coplanar waveguide (CPW) structure or an open stub of a micro-strip transmission line, thereby solving an impedance mismatch when a flexible PCB is electrically connected with a main board in a high-speed optical communication device. Further, a product can be produced by a fabricating process of the flexible PCB in the related art and a flexible PCB which can perform high-speed signal transmission may be fabricated at a low cost.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a graph showing a calculation result for a connection structure of a flexible PCB of the related art and a main PCB.

FIGS. 2A, 2B and 2C is a conceptual diagram showing a structure of a transmission line for data communication according to first exemplary embodiment of the present invention.

FIG. 3 is a graph comparing a reflection according to a method of the related art with a reflection according to a first exemplary embodiment of the present invention.

FIGS. 4A, 4B and 5 are conceptual diagrams showing a structure of a transmission line for data communication according to second exemplary embodiment of the present invention.

FIG. 6 is a graph comparing a reflection according to a method of the related art with a reflection according to a second exemplary embodiment of the present invention.

FIG. 7 is a flowchart showing a method for designing a transmission line for data communication according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, exemplary embodiments of the present invention will be described in detail with reference to the accompanying drawings. First of all, we should note that in giving reference numerals to elements of each drawing, like reference numerals refer to like elements even though like elements are shown in different drawings. Further, in describing the present disclosure, well-known functions or constructions will not be described in detail since they may unnecessarily obscure the understanding of the present disclosure. Hereinafter, the exemplary embodiment of the present invention will be described, but it will be understood to those skilled in the art that the spirit and scope of the present invention are not limited thereto and various modifications and changes can be made.

The present invention provides a structure of a data signal line on a flexible PCB for electric connection of a high-speed optical communication device. Particularly, the present invention provides a structure of a data signal line of a flexible PCB operable in a high frequency domain. In the exemplary embodiment, the optical communication device uses a transmitter optical sub-assembly (TOSA), a receiver optical sub-assembly (ROSA), and the like. The reason is because a TOSA module or a ROSA module is electrically connected to a transceiver main board by using a flexible PCB in many optical transceivers.

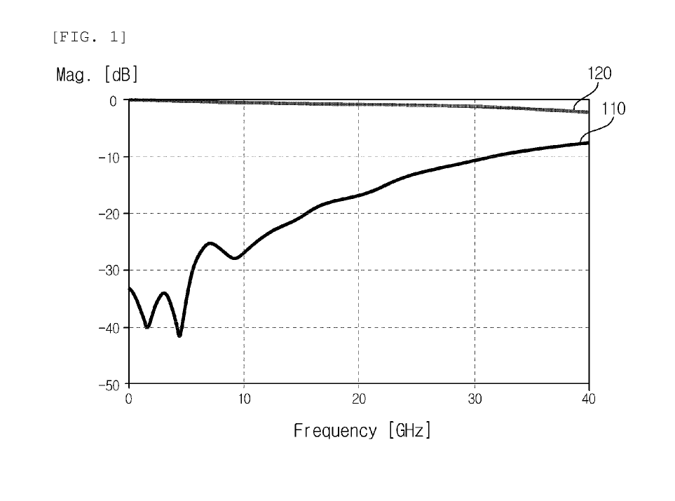

FIG. 1 is a graph showing a calculation result for a connection structure of a flexible PCB of the related art and a main PCB. FIG. 1 shows a calculation value of a transmission 120 and a reflection 110 when a flexible PCB and a main PCB (rigid PCB) are connected to each other by a method of the related art.

In a connection portion between the flexible PCB and the main board, a discontinuous surface of a ground is disposed at the bottom of the flexible PCB. The discontinuous surface is a discontinuous area for preventing a short when the flexible PCB is connected to the main board by soldering. Then, signal lines on the discontinuous area and via holes of a signal line pad operate like an inductance at a predetermined frequency or more, such that impedance mismatch occurs. As a result, the reflection 110 increases as the frequency increases. A portion connected with the flexible PCB module may have various shapes according to a module structure of through-holes or patterns on the signal line. In the frequency of 30 GHz or more, the reflection rapidly deteriorates by 10 dB or more. As a line width of the signal line pad for connecting a micro-strip transmission line having a characteristic impedance of 50 Ω with a small line width in the flexible PCB with the main board is rapidly increased, the deterioration of the reflection is also caused by the portion of the impedance mismatch. The length of the flexible PCB and the length of the main board (RO4350) that are used in calculation are results with respect to 12 mm and 15 mm to be used in the TOSA and the ROSA, respectively.

In order to solve the problem of FIG. 1, the exemplary embodiment of the present invention provides a structure of a data signal line on the flexible PCB which can be electrically connected to a high-speed optical communication device by modifying a shape of the signal line of the flexible PCB by using a coplanar waveguide (CPW) structure or an open stub of the micro-strip transmission line to impedance-match data signal lines between the flexible PCB and the main board.

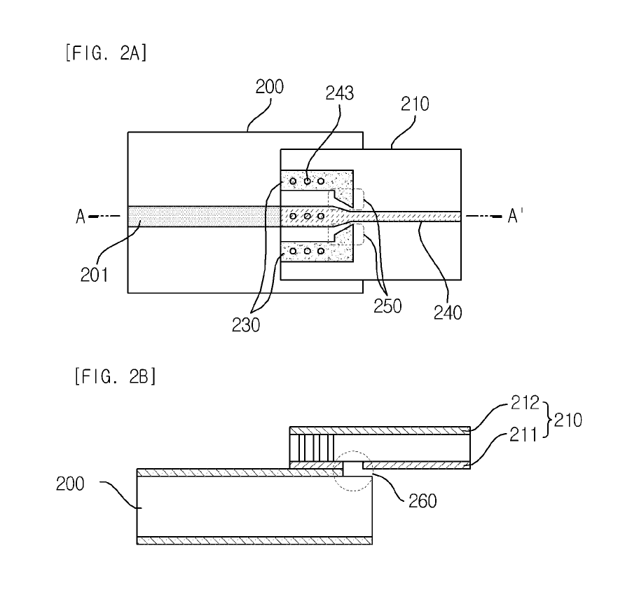

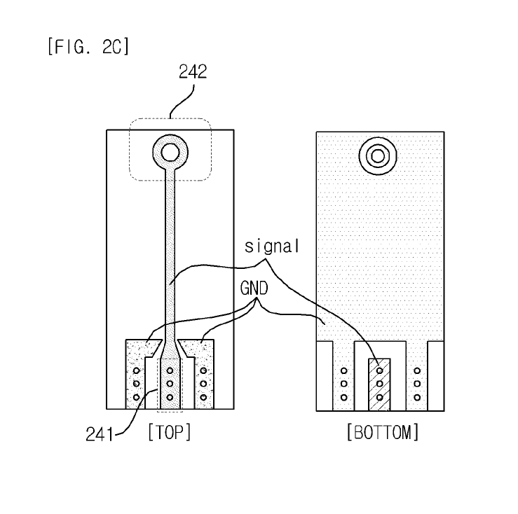

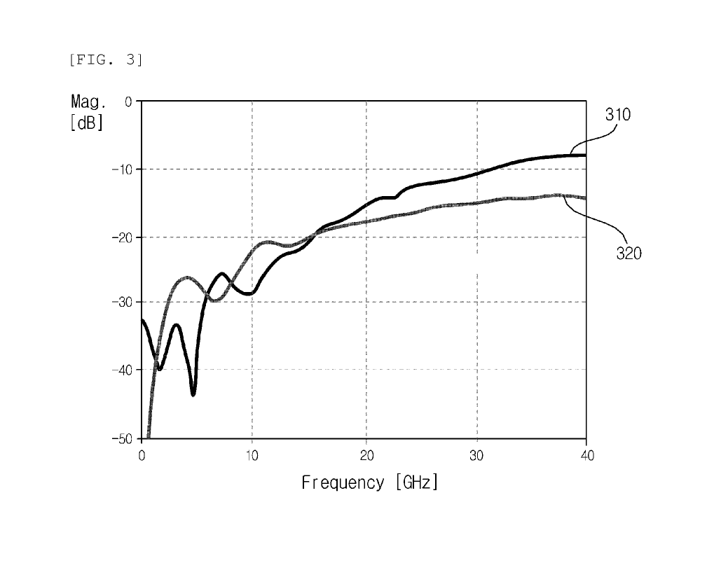

FIGS. 2A, 2B and 2C is a conceptual diagram showing a structure of a transmission line for data communication according to a first exemplary embodiment of the present invention. FIG. 2A is a plan view showing a structure of a transmission line for data communication according to the first exemplary embodiment of the present invention. FIG. 2B is a cross-sectional view of a structure of a transmission line for data communication according to the first exemplary embodiment of the present invention and is a cross-sectional view taken along line A-A′ of FIG. 2A (A-A′ section view). FIG. 2C is a diagram showing the top and the bottom of a second layer 212 shown in FIG. 2B.

Hereinafter, the following description refers to FIG. 2.

The structure of a transmission line for data communication according to the exemplary embodiment includes a first substrate layer 200 and a second substrate layer 210. The second substrate layer 210 has at least a part stacked on the first substrate layer 200 and includes a first layer 211 and a second layer 212.

A data transmission line is formed at one side of the first substrate layer 200. The first substrate layer 200 serves as a main board and is a printed circuit substrate (PCB) on which a main component for driving an optical communication device, for example, a central processing unit (CPU) is mounted.

The first layer 211 serves as a GND. A discontinuous surface of a ground plane is formed at one side of the first layer 211. The first layer 211 may also have a controlling/driving related signal line in addition to the GND function.

The second layer 212 has a data communication pattern 240 and GND patterns 230 which are disposed on the first layer 211 and formed at one side of the second layer 212. The second layer 212 may have only the data communication pattern 240 disposed on the discontinuous surface of the first layer 211 so as not to be parallel to the GND patterns 230. The data communication pattern 240 is connected to the data transmission line 201 on the first substrate layer 200. The GND patterns 230 are formed on the same surface as the data communication pattern 240, but are not parallel to the data communication pattern 240.

The second layer 212 has the data communication pattern 240 which is not parallel to the GND patterns 230 through first impedance matching patterns 250 extending from at least one side of the GND patterns 230 to protrude toward the data communication pattern 240. In the exemplary embodiment, the first impedance matching patterns 250 may be formed by applying the coplanar waveguide (CPW) structure.

One end of the first impedance matching patterns 250 is formed to protrude toward the data communication pattern 240 as compared with the other end thereof. In this case, the first impedance matching patterns 250 may be implemented in a triangular shape, for example, a right-triangular shape. For example, when the one end is a first end and the other end is a second end in the first impedance matching patterns 250, a distance from the first end to the data communication pattern 240 may be 10% to 30% and a distance from the second end to the data communication pattern 240 may be 70% to 90% with respect to a distance from the GND patterns 230 to the data communication pattern 240. The first impedance matching patterns 250 are disposed at the ends of the GND patterns 230.

The second substrate layer may be implemented by a flexible PCB, that is, an FPCB. In this case, the data communication pattern 240 of the second layer 212 may be connected to the data transmission line 201 formed on the first substrate layer 200 through at least one via hole formed therein and the GND patterns 230 of the second layer 212 formed at both sides of the data communication pattern 240 may be connected to the first layer 211 through at least one via hole 243 formed therein.

In order to prevent a short between the data signal line and the ground GND when the flexible PCB is connected to the main board, a discontinuous surface 260 is generally formed at the bottom ground surface of a signal having a transmission line structure (micro-strip structure). The discontinuous surface 260 is referred to as the discontinuous surface 260 of the GND plane (ground plane). For the impedance matching of the data signal line corresponding to the discontinuous surface 260, the co-planar wavelength (CPW) structure is applied as the first exemplary embodiment in FIG. 2A and FIG. 2B. In the case where the transmission line for data communication is implemented by the structure provided in FIG. 2A and FIG. 2B, a transition matching structure between the micro-strip and the CPW may be formed on the entire signal path.

Meanwhile, reference numeral 241 in FIG. 2C means a data signal line pad. The data signal line pad 241 is physically separated from the transmission line for data communication on the first substrate layer 200 and is connected to the transmission line for data communication by soldering and the like in connection. Reference numeral 242 means a portion connected with a module. In the exemplary embodiment, the connection with the module is not limited to the connection by holes and may be performed by various cases such as the connection through the pattern formation and the like.

FIG. 3 is a graph comparing a reflection 310 according to a method of the related art with a reflection 320 according to a first exemplary embodiment of the present invention. The following description refers to FIG. 3.

The reflection 320 according to the first exemplary embodiment of the present invention shows a good reflection of 10 dB or less even in a frequency domain of 30 GHz or more. A connection form to the signal line pad of the portion connected with the main board has a tapered form on the flexible PCB signal line. The connection form may also be implemented in a staircase form in addition to the tapered form. The connection form has a predetermined distance between the signal line pad and the top ground to enable the CPW structure. The CPW-applied structure is a structure for solving impedance discontinuity of the signal line corresponding to the discontinuous portion of the bottom ground. The portions connected with the module of the flexible PCB may be connected with each other by the through-hole or by forming patterns on the signal line as shown in FIG. 2B according to the structure of the module. The portions may have various types of connection forms in addition to the method. The length of the flexible PCB and the length of the main board (RO4350) that are used in calculation are results with respect to 12 mm and 15 mm to be used in the TOSA and the ROSA, respectively.

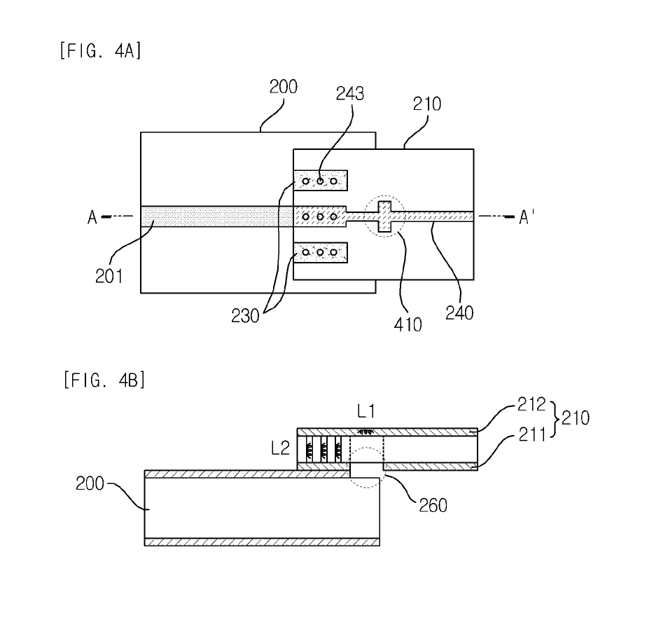

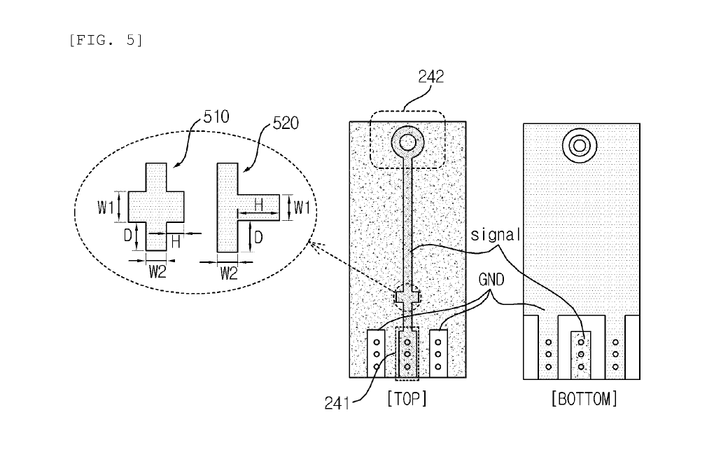

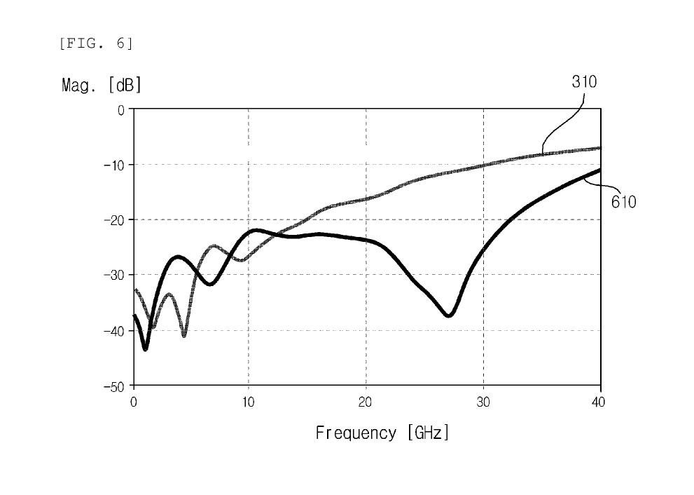

FIGS. 4A, 4B and 5 are conceptual diagrams showing a structure of a transmission line for data communication according to second exemplary embodiment of the present invention. FIG. 4A is a plan view showing a structure of a transmission line for data communication according to the second exemplary embodiment of the present invention. FIG. 4B is a cross-sectional view of a structure of a transmission line for data communication according to the second exemplary embodiment of the present invention, which is taken along line A-A′ of FIG. 4A (A-A′ section view). FIG. 5 is a diagram showing the top and the bottom of a second layer 212 shown in FIG. 4B. The following description refers to FIGS. 4A, 4B and 5.

The second layer 212 has the data communication pattern 240 which are not parallel to the GND patterns 230 through a second impedance matching pattern 410 formed by extending from at least one side of the data communication pattern 240 to protrude toward the GND patterns 230. The second impedance matching pattern 410 may be implemented in an open stub form. For example, the second impedance matching pattern 410 may be implemented in a single open stub form like reference numeral 520 of FIG. 5 or in a cross open stub form like reference numeral 510 of FIG. 5.

One end and the other end of the second impedance matching pattern 410 are formed to equally protrude toward the GND patterns 230. In the exemplary embodiment, the second impedance matching pattern 410 may be implemented in a quadrangular shape (ex. rectangular shape) or a conic shape. The second impedance matching pattern 410 is formed at the side which does not face the GND patterns 230.

When the second impedance matching pattern 410 is formed at one side of the data communication pattern 240, a length of the second impedance matching pattern 410 is set as a value larger than a width of the second impedance matching pattern 410. For example, in the case where the second impedance matching pattern 410 is formed only at one side of the data communication pattern 240, when the one end of the second impedance matching pattern 410 is a first end and the other end thereof is a second end, a distance D from a point meeting with a vertical line bounded on an end portion of the GND patterns 230 to the second impedance matching pattern 410 may be 130% to 160%, a length H of the second impedance matching pattern 410 may be 140% to 170%, and a width W1 of the second impedance matching pattern 410 may be 90% to 110%, with respect to a width W2 of the data communication pattern 240. Meanwhile, the length of the second impedance matching pattern 410 may be set to be the same as a length of the discontinuous surface 260 of the GND plane.

When the second impedance matching pattern 410 is formed at both sides of the data communication pattern 240, the width of the second impedance matching pattern 410 is set to have a larger value than the length of the second impedance matching pattern 410. For example, in the case where the second impedance matching pattern 410 is formed at both sides of the data communication pattern 240, when the one end of the second impedance matching pattern 410 is the first end and the other end thereof is the second end, the distance D from a point meeting with a vertical line bounded on an end portion of the GND patterns 230 to the second impedance matching pattern 410 may be 120% to 150%, the length H of the second impedance matching pattern 410 may be 90% to 110%, and the width W1 of the second impedance matching pattern 410 may be 140% to 170%, with respect to the width W2 of the data communication pattern 240. Meanwhile, the length of the second impedance matching pattern 410 may be set to be the same as the length of the discontinuous surface 260 of the GND plane.

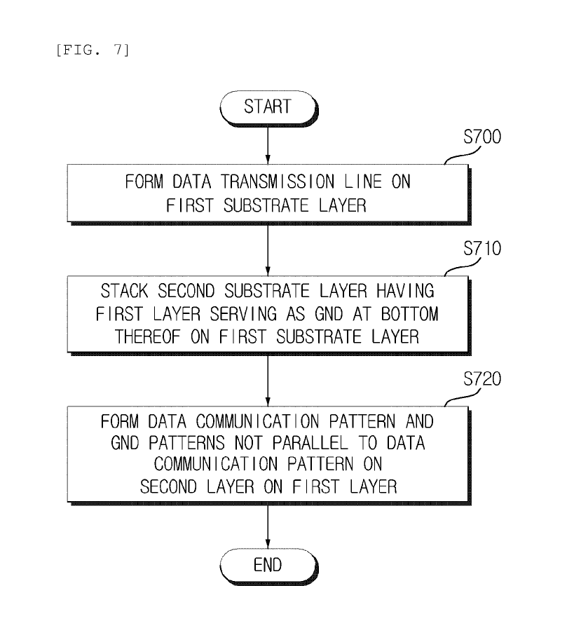

FIG. 6 is a graph comparing a reflection 310 according to a method of the related art with a reflection 610 according to a second exemplary embodiment of the present invention. The following description refers to FIGS. 4A to 6.

In order to prevent a short between the data signal line and the ground when the flexible PCB is connected to the main board, the discontinuous surface 260 is generally formed at the bottom ground surface of a signal having a transmission line structure (micro-strip structure). Further, the line width of the data communication pattern 240 rapidly increases toward the data signal line pad 241 in the transmission line structure (micro-strip structure) and an impedance continuous point is formed by a via hole for connecting the first substrate layer and the second substrate layer. As described above, in the second exemplary embodiment, an open stub method is used for the impedance matching of the data signal line corresponding to the impedance discontinuous portion. The reflection may be largely improved by performing a resonance of an inductance component L1 of the signal line corresponding to the discontinuous surface and an inductance component L2 corresponding to a via hole of the signal line pad for the connection with the main board in a desired frequency band by using a micro-strip open stub on the flexible PCB.

The open stub may be implemented in the single open stub form and the cross open stub form as shown in FIG. 5. The portions connected with the module of the flexible PCB may be connected with each other by using the through-hole or by forming a pattern on the signal line according to the structure of the module. The portions may have various types of connection forms in addition to the method.

FIG. 6 shows a calculated reflection when the length of the flexible PCB is 12 mm and the length of the main board (RO4350) is 15 mm. The reflection may be largely improved by generating the resonance in a desired frequency according to standards W1, W2, H, and D of the open stub. Herein, D is a length of the top signal line corresponding to the bottom ground discontinuous area. The length of the flexible PCB and the length of the main board (RO4350) that are used in calculation are results with respect to 12 mm and 15 mm to be used in the TOSA and the ROSA, respectively.

Next, a method for designing a transmission line for data communication by using a printed circuit board (PCB) will be described. FIG. 7 is a flowchart showing a method for designing a transmission line for data communication according to an exemplary embodiment of the present invention. The following description refers to FIG. 7.

First, a data transmission line is formed at one side of a first substrate layer (forming of the transmission line, S700).

After the forming of the transmission line (S700), at least a part of a second substrate layer having a first layer serving as a GND at the bottom thereof is stacked on the first substrate layer (stacking, S710). In the stacking (S710), a discontinuous surface of a ground plane may be formed at one side of the first layer.

After the stacking (S710), a data communication pattern connected to the data transmission line and GND patterns which are not parallel to the data transmission pattern are formed at one side of a second layer disposed on the first layer included in the second substrate layer (forming patterns, S720). In the forming of the patterns (S720), only the data communication pattern disposed on the discontinuous surface of the first layer may be formed so as not to be parallel to the GND patterns.

When the data communication pattern is formed so as not to be parallel to the GND patterns, in the forming of the patterns (S720), as a first type, first impedance matching patterns extending from at least one side of the GND patterns is formed to protrude toward the data communication pattern. In this case, one end of the first impedance matching patterns is formed to protrude more toward the data communication pattern as compared with the other end of the first impedance matching patterns. The first impedance matching patterns are formed at the end of the GND patterns.

When the data communication pattern is formed so as not to be parallel to the GND patterns, in the forming of the patterns (S720), as a second type, a second impedance matching pattern extending from at least one side of the data communication pattern is formed to protrude toward the GND patterns, such that the data communication pattern is formed not to be parallel to the GND patterns. In this case, one end of the second impedance matching pattern and the other end of the second impedance matching pattern are formed to equally protrude toward the GND patterns. The second impedance matching pattern is formed at the side which does not face the GND patterns.

When the second impedance matching pattern is formed at one side of the data communication pattern, a length of the second impedance matching pattern is set to have a larger value than a width of the second impedance matching pattern. On the contrary, when the second impedance matching pattern is formed at both sides of the data communication pattern, the width of the second impedance matching pattern is set to have a larger value than the length of the second impedance matching pattern.

Meanwhile, in the forming of the patterns (S720), the second substrate layer may use a flexible printed circuit board (PCB), that is, an FPCB. In the forming of the patterns (S720), the data communication pattern of the second layer may be connected to the data transmission line formed on the first substrate layer through at least one via hole formed therein and the GND patterns of the second layer formed at both sides of the data communication pattern may be connected to the first layer through at least one via hole formed therein.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A structure of a transmission line for data communication, comprising:
a first substrate layer with a data transmission line at one side thereof; and
a second substrate layer having at least a part stacked on the first substrate layer and including a first layer serving as a GND and a second layer provided on the first layer and having a data communication pattern connected to the data transmission line and GND patterns which are not parallel to the data communication pattern which are formed at one side thereof.

2. The structure of a transmission line for data communication of claim 1, wherein the first layer has a discontinuous surface formed at one side thereof and the second layer has only the data communication pattern disposed on the discontinuous surface so as not to be parallel to the GND patterns.

3. The structure of a transmission line for data communication of claim 1, wherein the second layer has the data communication pattern so as not to be parallel to the GND patterns through first impedance matching patterns extending from at least one side of the GND patterns to protrude toward the data communication pattern or the data communication pattern so as not to be parallel to the GND patterns through a second impedance matching pattern extending from at least one side of the data communication pattern to protrude toward the GND patterns.

4. The structure of a transmission line for data communication of claim 3, wherein one end of the first impedance matching patterns is formed to protrude more toward the data communication pattern than the other end thereof.

5. The structure of a transmission line for data communication of claim 4, wherein the first impedance matching patterns are disposed at the ends of the GND patterns.

6. The structure of a transmission line for data communication of claim 3, wherein one end and the other end of the second impedance matching pattern are formed to equally protrude toward the GND patterns.

7. The structure of a transmission line for data communication of claim 6, wherein when the second impedance matching pattern is formed at one side of the data communication pattern, a length of the second impedance matching pattern is set to have a larger value than a width of the second impedance matching pattern and when the second impedance matching pattern is formed at both sides of the data communication pattern, the width of the second impedance matching pattern is set to have a larger value than the length of the second impedance matching pattern.

8. The structure of a transmission line for data communication of claim 3, wherein the second impedance matching pattern is formed at the side which does not face the GND patterns.

9. The structure of a transmission line for data communication of claim 1, wherein the second substrate layer is flexible.

10. A method for designing a transmission line for data communication, comprising:
forming a data transmission line at one side of a first substrate layer;
stacking at least a part of a second substrate layer having a first layer serving as a GND at the bottom thereof on the first substrate layer; and
forming a data communication pattern connected to the data transmission line and GND patterns which are not parallel to the data transmission pattern at one side of a second layer disposed on the first layer included in the second substrate layer.

11. The method for designing a transmission line for data communication of claim 10, wherein in the stacking, a discontinuous surface is formed at one side of the first layer and in the forming of the patterns, only the data communication pattern disposed on the discontinuous surface is formed so as not to be parallel to the GND patterns.

12. The method for designing a transmission line for data communication of claim 10, wherein in the forming of the patterns, the data communication pattern is formed so as not to be parallel to the GND patterns by forming first impedance matching patterns extending from at least one side of the GND patterns so as to protrude toward the data communication pattern, or the data communication pattern is formed so as not to be parallel to the GND patterns by forming a second impedance matching pattern extending from at least one side of the data communication pattern so as to protrude toward the GND patterns.

13. The method for designing a transmission line for data communication of claim 12, wherein in the forming of the patterns, one end of the first impedance matching patterns is formed to protrude more toward the data communication pattern than the other end of the first impedance matching patterns.

14. The method for designing a transmission line for data communication of claim 12, wherein in the forming of the patterns, one end and the other end of the second impedance matching pattern are formed to equally protrude toward the GND patterns.

15. The method for designing a transmission line for data communication of claim 14, wherein in the forming of the patterns, when the second impedance matching pattern is formed at one side of the data communication pattern, a length of the second impedance matching pattern is set to have a larger value than a width of the second impedance matching pattern and when the second impedance matching pattern is formed at both sides of the data communication pattern, the width of the second impedance matching pattern is set to have a larger value than the length of the second impedance matching pattern.
